(19) United States
(12) Patent Application Publication
(10) Pub. No.: US 2012/0236215 A1
(43) Pub. Date: Sep. 20, 2012

(54) TV RECEIVER AND ELECTRONIC APPARATUS

(76) Inventor: Takuo Matsumoto, Hamura-shi (JP)

(21) Appl. No.: 13/371,219

(22) Filed: Feb. 10, 2012

(30) Foreign Application Priority Data
Mar. 16, 2011 (JP) 2011-058319

(51) Int. Cl. H04N 5/64; H05K 5/00

(52) U.S. Cl. 348/836; 361/724; 348/E05.128

(57) ABSTRACT

A TV receiver includes a cabinet, a circuit board, an electronic component, a reinforcement plate, and a projection. The cabinet has a wall that is provided with a manipulation surface. The circuit board is housed in the cabinet. The electronic component is provided on the circuit board. The reinforcement plate has a first surface that is in contact with the circuit board and a second surface that is opposite to the first surface and is exposed to an internal space of the cabinet. The projection that is located in a region of the wall on a back side of the manipulation surface, and is projected from the region toward the reinforcement plate, and configured to come into contact with the reinforcement plate to suppress deformation of the wall when the wall is bent toward the internal space of the cabinet.

### CROSS REFERENCE TO RELATED APPLICATION(S)

The present disclosure relates to the subject matters contained in Japanese Patent Application No. 2011-058319 filed on Mar. 16, 2011, which are incorporated herein by reference in its entirety.

### FIELD

An exemplary embodiment of the present invention relates to a TV receiver and an electronic apparatus.

### BACKGROUND

Electronic apparatus in which a reinforcement plate is disposed along a circuit board are known.

Electronic apparatus of the above kind are desired to be stronger.

### BRIEF DESCRIPTION OF THE DRAWINGS

A general configuration that implements the various features of the invention will be described with reference to the drawings. The drawings and the associated descriptions are provided to illustrate embodiments of the invention and should not limit the scope of the invention.

FIG. 1 is a front view of an example TV receiver according to a first embodiment.

FIG. 2 is a perspective view of part of an example circuit board of the TV receiver according to the first embodiment.

FIG. 3 is a perspective view of the same portion as shown in FIG. 2 and shows a state that a wireless LAN module is removed.

FIG. 4 is a perspective view of a reinforcement plate used in the TV receiver according to the first embodiment.

FIG. 5 is a perspective view of the example wireless LAN module used in the TV receiver according to the first embodiment.

FIG. 6 is a perspective view of an example notebook personal computer according to a second embodiment which is in an open state.

FIG. 7 is a perspective view of an example upper portion of a cabinet of the personal computer according to the second embodiment as viewed from an inner side of the cabinet.

FIG. 8 is a bottom view showing the inside of an example first unit of the personal computer according to the second embodiment with a lower portion of a cabinet removed.

FIG. 9 is a bottom view of an example circuit board of the personal computer according to the second embodiment as viewed from one surface (i.e., from the back side).

FIG. 10 is a plan view the circuit board of the personal computer according to the second embodiment as viewed from the side of the other surface.

FIG. 11 is a perspective view of an example portion, provided with a reinforcement plate in association with one module, of the circuit board of the personal computer according to the second embodiment.

FIG. 12 is a perspective view of a reinforcement plate used in the personal computer according to the second embodiment.

FIG. 13 shows an example region, where the reinforcement plate is to be disposed, of the circuit board of the personal computer according to the second embodiment.

FIG. 14 is a perspective view of the same portion as shown in FIG. 11 and shows a state that a wireless LAN module is removed.

FIG. 15 is a perspective view of an example wireless LAN module used in the personal computer according to the second embodiment.

FIG. 16 is a sectional view taken along line XVI-XVI in FIG. 9.

FIG. 17 is a sectional view of part of the first unit of the personal computer according to the embodiment.

FIG. 18 is a sectional view of part of an example circuit board having a reinforcement plate used in a personal computer according to a first modification.

FIG. 19 is a sectional view of part of an example circuit board having a reinforcement plate used in a personal computer according to a second modification.

FIG. 20 is a perspective view of a reinforcement plate used in a personal computer according to a third modification.

FIG. 21 is a perspective view of a reinforcement plate used in a personal computer according to a fourth modification.

FIG. 22 is a perspective view of a reinforcement plate used in a personal computer according to a fifth modification.

FIG. 23 is a sectional view of part of an example circuit board having a reinforcement plate used in a personal computer according to a sixth modification.

FIG. 24 is a sectional view of part of an example circuit board having a connector (support member) used in a personal computer according to a seventh modification.

FIG. 25 is a sectional view of a modification of the reinforcement plate shown in FIG. 17.

FIG. 26 is a sectional view of another modification of the reinforcement plate shown in FIG. 17.

### DETAILED DESCRIPTION OF THE EMBODIMENTS

According to one embodiment, there is provided a TV receiver including a cabinet, a circuit board, an electronic component, a reinforcement plate, and a projection. The cabinet has a wall that is provided with a manipulation surface. The circuit board is housed in the cabinet. The electronic component is provided on the circuit board. The reinforcement plate has a first surface that is in contact with the circuit board and a second surface that is opposite to the first surface and is exposed to an internal space of the cabinet. The projection that is located in a region of the wall on a back side of the manipulation surface, and is projected from the region toward the reinforcement plate, and configured to come into contact with the reinforcement plate to suppress deformation of the wall when the wall is bent toward the internal space of the cabinet.

Embodiments of the present invention will be hereinafter described in detail. Plural embodiments and modifications described below have sets of same constituent elements, which will be given common reference symbols and will not be described redundantly. For the sake of convenience, directions are defined in each of the drawings for description of the embodiments. The X, Y and Z directions represent the right-left direction, the height (or depth) direction, and the thickness direction, respectively, of a cabinet 2a which is configured according to the invention. The X, Y and Z directions are orthogonal to each other.

### First Embodiment

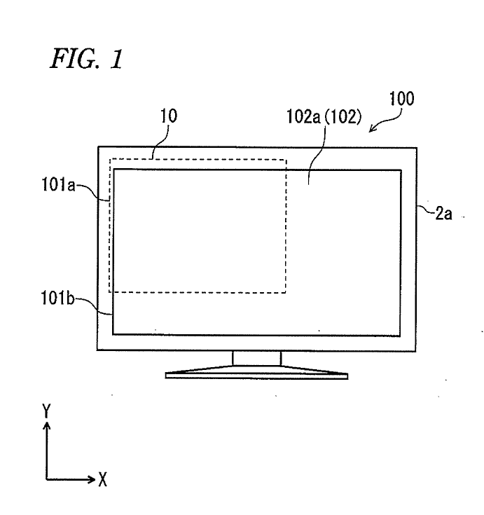

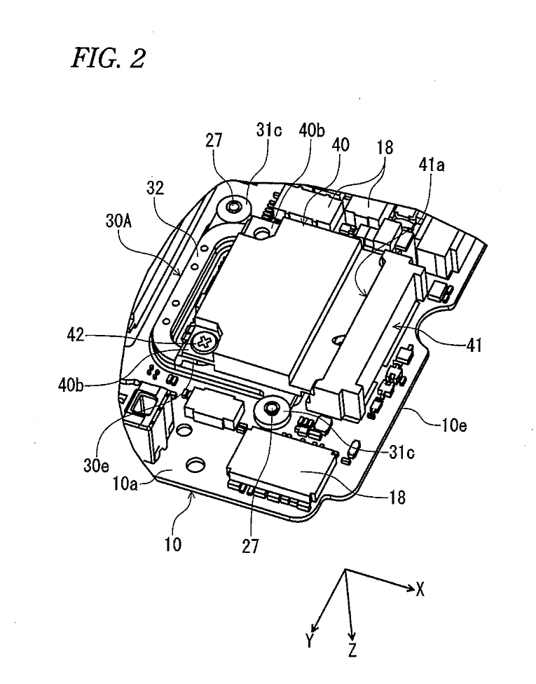

FIG. 1 is a front view of a TV receiver (TV apparatus, video display apparatus) 100 according to a first embodiment which is an example electronic apparatus. As shown in FIG. 1, the TV receiver 100 has a rectangular appearance that is long in the horizontal direction (X direction) and short in the vertical direction (Y direction) when viewed from the front side (i.e., in a plan view for the front surface). The TV receiver 100 is equipped with the cabinet 2a, a display panel (e.g., LCD (liquid crystal display) or OELD (organic electroluminescent display) 102 as a display module (display unit, module) having a display screen 102a which is exposed to the front side through an opening 101b of a front surface 101a of the cabinet 2a, a board 10 which is mounted with devices (components, electronic components, modules) 18 (see FIG. 2 etc.), etc. The display panel 102 and the board 10 are fixed to the cabinet 2a with screws or the like (not shown).

The display panel 102 has a rectangular parallelepiped shape that is thin and flat in the front-rear direction (the direction perpendicular to the paper surface of FIG. 1, Z direction; also see FIG. 2 etc.). The display panel 102 receives a video signal from a video signal processing circuit (not shown) of control circuits (not shown) which are composed of the devices 18 (see FIG. 2 etc.) mounted on the board 10 and displays video (e.g., a still image or a moving image) on its front display screen 102a. The control circuits of the TV receiver 100 have, in addition to the video signal processing circuit, a tuner unit, an HDMI (high-definition multimedia interconnect) signal processing section, AV (audio-video) input terminals, an remote control signal receiving unit, a control section, a selector, an on-screen display interface, storage units (e.g., ROM (random access memory), RAM (read-only memory), and HDD (hard disk drive)), an audio signal processing circuit, etc. (non of them are shown in FIG. 1). The substrate 10 is housed in the cabinet 2a in the rear of the display panel 102. The TV receiver 100 also incorporates an amplifier, speakers, etc. (none of them are shown in FIG. 1) for audio output.

FIG. 2 is a perspective view of the backside of a portion, mounted with modules (not shown), of the circuit board 10. A reinforcement plate 30A is provided on this backside surface. As shown in FIG. 2, the reinforcement plate 30A is covered with a wireless LAN (local area network) module 40. The wireless LAN module 40 is connected to a connector 41, which is an example housed component (module, component).

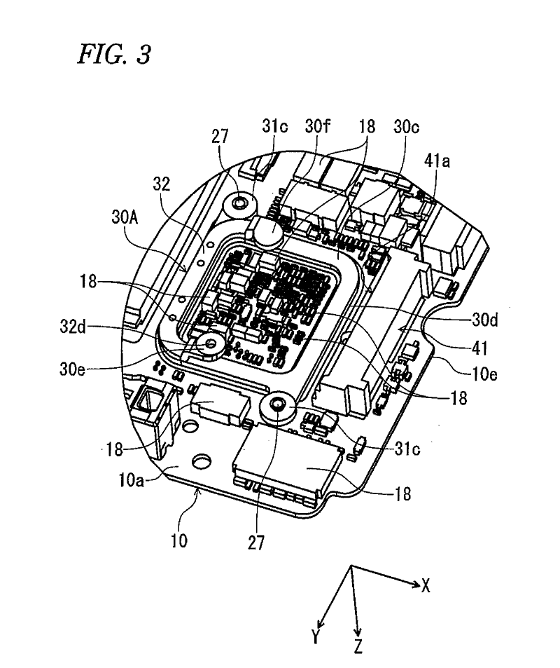

FIG. 3 is a perspective view of the same portion as shown in FIG. 2 and shows a state that the wireless LAN module 40 is removed, that is, a state before attachment of the wireless LAN module 40. As shown in FIG. 3, plural, relatively small (low-height) devices (components) 18 are mounted on a surface 10a of the circuit board 10 inside the reinforcement plate 30A. The reinforcement plate 30A is located in a region where no devices 18 are mounted. The reinforcement plate 30A is fixed to the circuit board 10 in such a manner that fixing members 27 are fastened to respective projections 31c. The devices 18 that are disposed inside the region where no devices 18 are mounted are example third modules.

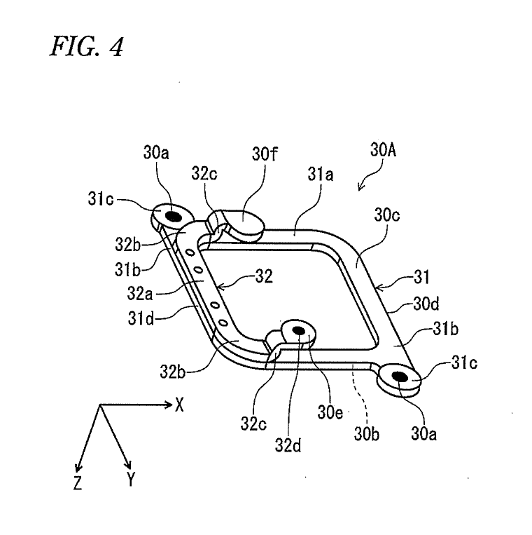

FIG. 4 is a perspective view of the reinforcement plate 30A. The reinforcement plate 30A is an integral member of a first member 31 and a second member 32. The first member 31 has an annular portion 31a, corner portions 31b, the projections 31c, and an end portion 31d. The annular portion 31a is shaped like a rectangular ring. The corner portions 31b are located at diagonal positions of the annular portion 31a. The projections 31c project from the respective corner portions 31b away from the annular portion 31a and are shaped like a circular disc. The projections 31c are formed with respective screw holes 30a. The end portion 31d is an example of one side portion of the annular portion 31a.

The second member 32 has a base portion 32a, end portions 32b, projections 32c, and receiving portions 30e and 30f. The base portion 32a is placed on and extends along the end potion 31d of the first member 31. The base portion 32a is bent at both end portions 32b and thereby shaped like a character U. The projections 32c project (are erected) from both end portions 32b away from the first member 31. The receiving portions 30e and 30f are located at the tips of the respective projections 32c, are parallel with the first member 31, and are shaped like a circular disc. The receiving portion 30e is formed with a female screw 32d. In the embodiment, the second member 32 is an example support portion and the base portion 32a is an example first end portion.

The first member 31 and the second member 32 are integrated with (connected to) each other by welding (e.g., spot welding), for example. In the embodiment, for example, the end portion 31d of the first member 31 and the base portion 32a of the second member 32 are connected to each other at plural positions (e.g., four positions) by spot welding.

Each reinforcement plate 30 is disposed parallel with the surface 10a or a surface 10b (not shown) of the circuit board 10 preferably in contact with the surface 10a or 10b. In the embodiment, the reinforcement plate 30A is disposed on the side of the surface 10a and has a first surface (not shown) that is in contact with the surface 10a and a second surface 30c that is opposite to the first surface and is exposed to the inside space of the cabinet 2a. Where a reinforcement plate 30 is disposed on the side of the surface 10b of the circuit board 10, its first surface is in contact with the surface 10b and its second surface 30c is exposed to the inside space of the cabinet 2a.

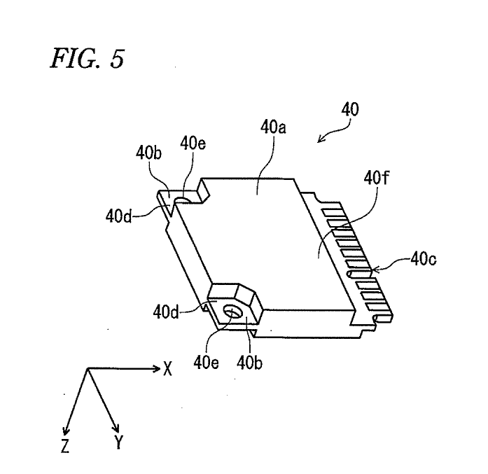

FIG. 5 is a perspective view of the wireless LAN module 40. The wireless LAN module 40 has a rectangular or square appearance when viewed in the thickness direction (Z direction). The wireless LAN module 40 has a body (housing) 40a, flanges 40b, and connector pins 40c. The body 40a has a flat, rectangular parallelepiped shape. The flanges 40b are relatively thin, plate-like portions which are two corner portions 40d located at the two ends of one sideline of the rectangle. Through-holes 40e are formed through the respective flanges 40b. The connector pins 40c extend outward from an end portion (side portion) 40f that is opposite to the two corner portions 40d so as to have approximately a constant length, and are arranged alongside the end portion 40f.

As shown in FIGS. 2, 3, etc., a connector 41 has a long and narrow rectangular parallelepiped shape. The connector 41 is disposed between an edge 10e of the circuit board 10 and an edge 30d of the reinforcement plate 30A and extends alongside the edge 10e. The edge 10e of the circuit board 10, the connector 41, and the edge 30d of the reinforcement plate 30A are parallel with each other. The connector 41 is fixed to the surface 10a by soldering, for example.

A worker inserts the connector pins 40c of the wireless LAN module 40 into a connection portion 41a of the connector 41 and then puts the flanges 40b of the wireless LAN module 40 on the respective receiving portions 30e and 30f of the reinforcement plate 30A. Then, the worker fastens a fixing member 42 such as a screw that is inserted in the through-hole 40e of the one flange 40b to the female screw hole 32d of the receiving portion 30e of the reinforcement plate 30A. Whereas the connection portion 41a allows the wireless LAN module 40 to move in such a direction that the connector pins 40c are released from the connection portion 41a (leftward in FIGS. 2 and 3) and to rotate in such a direction that the flanges 40b are elevated, the connection portion 41a prohibits the wireless LAN module from moving or rotating in the other directions.

Therefore, when the one flange 40b is fixed to the receiving portion 30e with the fixing member 42, the wireless LAN module 40 can be fixed so as to maintain the state of FIG. 2. As such, the receiving portion 30e is an example stopping portion (fixing portion). On the other hand, the other flange 40b is placed on but is not fixed to the receiving portion 30f. As such, the receiving portion 30f is an example placement portion (support portion). The receiving portion 30e is an example second end portion and the receiving portion 30f is an example third end portion.

In the above-described manner, the wireless LAN module 40 is disposed over and parallel with the surface 10a of the circuit board 10 at such a position as to be distant from the surface 10a. Both ends of the wireless LAN module 40 are supported by the reinforcement plate 30A and the connector 41.

In the embodiment having the above configuration, the reinforcement plate 30A is used for supporting and fixing the wireless LAN module 40 which is an example housed component (module, component). Therefore, the number of components can be made smaller than in a case that the circuit board 10 is provided with separate components for supporting and fixing the wireless LAN module 40, which in turn makes it easier to arrange interconnections on the circuit board 10.

In the embodiment, the reinforcement plate 30A has the second member 32 as a support portion. Therefore, the reinforcement plate 30A can be increased in rigidity and can be manufactured more easily. The reinforcement plate 30A having the function of supporting and fixing a housed component can be manufactured more efficiently by effectively utilizing a conventional reinforcement plate having no support portions. Furthermore, both of the functions (the reinforcement of the circuit board 10 and the support and fixing of a housed component) of the reinforcement plate 30A can be satisfied more easily by, for example, making the specifications (material quality, flexural rigidity, etc.) of the first member 31 different from those of the second member 32. The first member 31 and the second member 32 may be connected to each other by a method other than welding, such as screwing, bonding, or engaging. The first member 31 and the second member 32 may be made of a metal material, a synthetic resin material, or the like.

### Second Embodiment

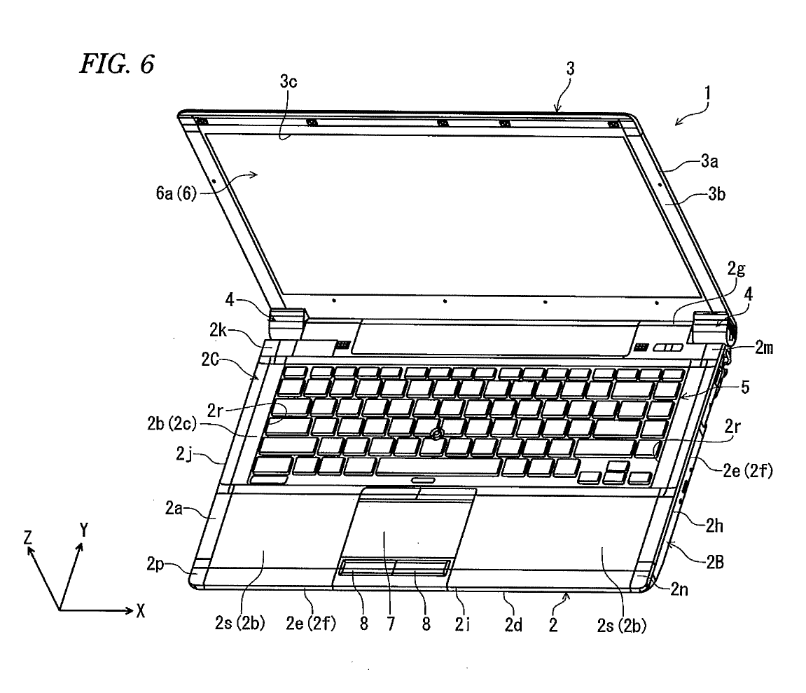

FIG. 6 is a perspective view of a notebook personal computer 1 according to a second embodiment which is in an open state. The notebook personal computer 1 is another example electronic apparatus. The personal computer 1 has a rectangular, flat first unit 2 and a rectangular, flat second unit 3 which are connected to each other by hinge mechanisms 4 so as to be rotated with respect to each other between an open state (see FIG. 6) and a folded state (not shown).

The first unit 2 is provided with a keyboard 5 as an input manipulation unit (module, input device, manipulation unit, input unit), a pointing device 7, click buttons 8, etc. in such a manner that they are exposed in a top surface (outside surface) 2b of a cabinet 2a. The second unit 3 is provided with a display panel (e.g., LCD (liquid crystal display) or OELD (organic electroluminescent display) 6 as a display module (module, display device, output unit) in such a manner that a display screen 6a is exposed through an opening 3c of a front surface 3b (outside surface) of a cabinet 3a. In the open state, the keyboard 5, the display panel 6, etc. are exposed and the personal computer 1 is usable by the user. On the other hand, in the folded state, the top surface 2b and the front surface 3b are opposed to each other in close proximity and the keyboard 5, the display panel 6, the pointing device 7, the click buttons 8, etc. are hidden by the cabinets 2a and 3a.

The cabinet 2a of the first unit 2 has a rectangular, plate-like top wall 2c having the top surface 2b, a rectangular, plate-like bottom wall 2d having a bottom wall (not shown), and a side wall (circumferential wall, vertical wall, erect wall) 2f having a side surface (circumferential surface) 2e. The bottom wall 2d is opposite to the top wall 2c with a space interposed in between. The side wall 2f crosses (is approximately perpendicular to) the top wall 2c and the bottom wall 2d and connects them. The top wall 2c, bottom wall 2d, and side wall 2f are example walls.

The cabinet 2a has an upper portion (upper cabinet, cover) 2C and a lower portion (lower cabinet, bottom) 2B. The cabinet 2a is formed by integrating the upper portion 2C and the lower portion 2B. The upper portion 2C includes the top wall 2c and may include part of the side wall 2f. The lower portion 2B includes the bottom wall 2d and may include part of the side wall 2f.

The cabinet 2a has four end portions (side portions) 2g, 2h, 2i, and 2j and four corner portions 2k, 2m, 2n, and 2p. The end portion 2g is an example rear end portion, the end portion 2i is an example front end portion which is opposite to the rear end portion, the end portion 2h is an example right end portion (side end portion), and the end portion 2j is an example left end portion (side end portion) which is opposite to the right end portion. The top surface (part of a manipulation surface, part of a manipulation portion, part of a receiving portion, part of an input receiving portion) 2b is formed with a recess 2r which is long in the right-left direction (X direction). The keyboard 5 is housed (placed) in the recess 2r.

The top wall 2c is provided with a palm rest 2s on the user's side of the recess 2r. The palm rest 2s has a relatively flat top surface. The top surface of the keyboard 5 which is housed (placed) in the recess 2r and the top surface of the palm rest 2s can be set flush with each other.

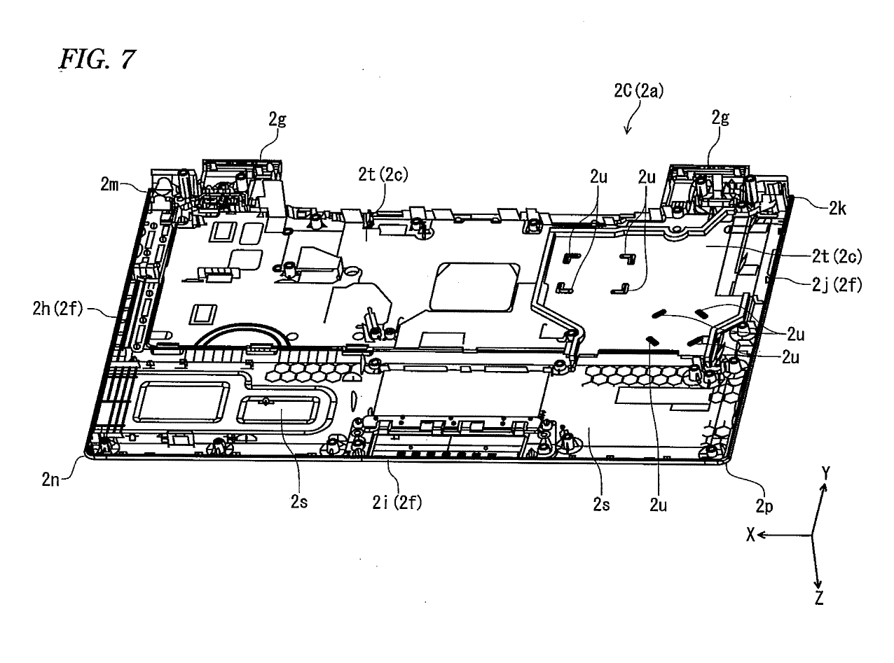

FIG. 7 is a perspective view of an example of the upper portion 2C of the cabinet 2a as viewed from the inner side of the cabinet (i.e., from the side of a back surface 2t). As shown in FIG. 7, the back surface 2t of the top wall 2c is provided with plural projections 2u.

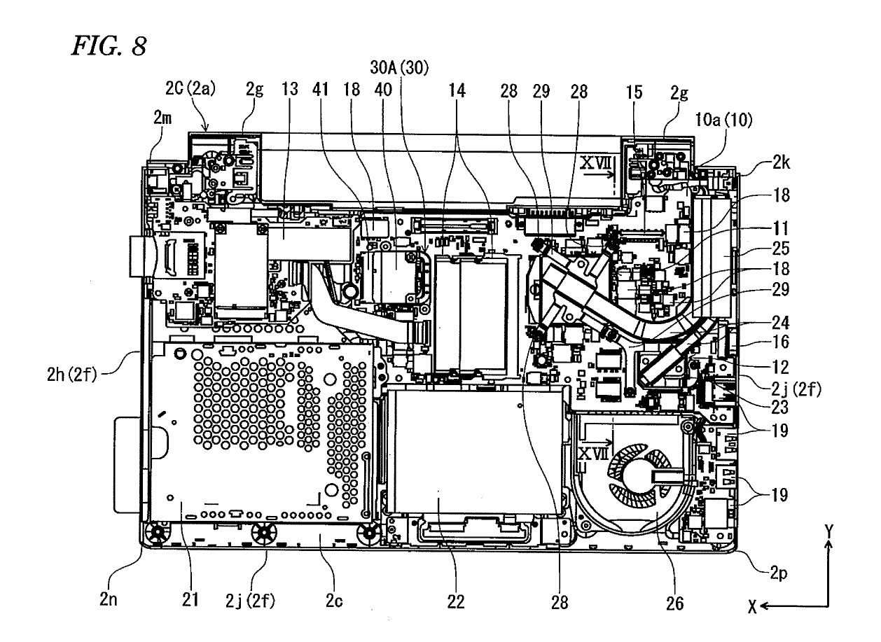

FIG. 8 is a bottom view showing the inside of an example of the first unit 2 with the lower portion 2B removed. The cabinet 2a of the first unit 2 houses a circuit board (board, printed circuit board, control board) 10, an ODD (optical disc drive) 21, a storage device 22, a heat sink 23, a heat pipe 24, a radiator plate 25, a cooling fan 26, etc. The circuit board 10 is a main board, for example. In the embodiment, one ends (not shown) of the hinge mechanisms 4 are attached to these components (e.g., circuit board 10, ODD 21, storage device 22, heat sink 23, heat pipe 24, radiator plate 25, and cooling fan 26). At this time, the other ends of the hinge mechanisms 4 have already been attached to the second unit 3 assembled. Then, the lower portion 2B is attached to the upper portion 2C.

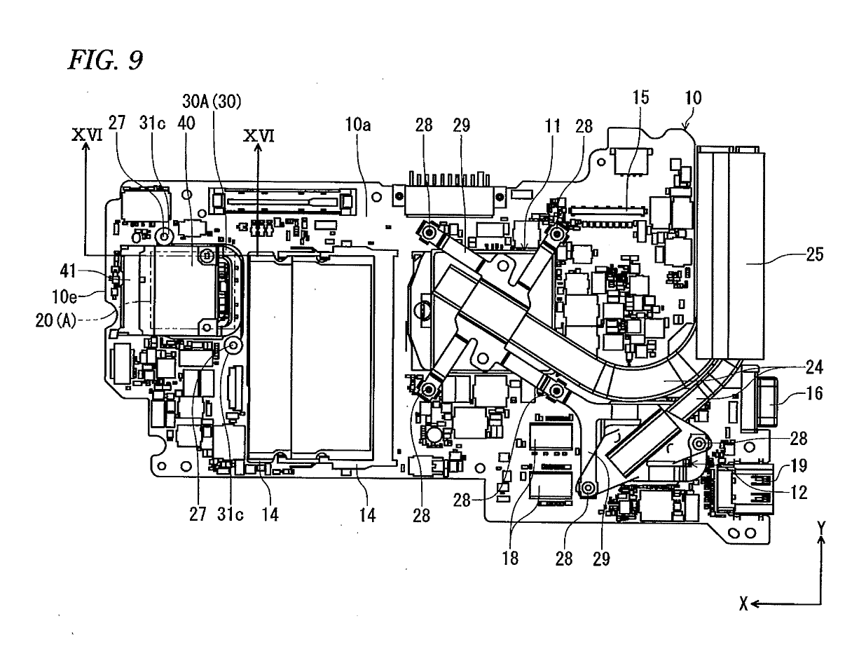

FIG. 9 is a bottom view of the circuit board 10 as viewed from the back side (i.e., from the side of a surface 10a). The surface 10a of the circuit board 10 is mounted with a CPU (central processing unit) 11, a graphic controller 12, a power circuit component 13, memory slot connectors 14, an LCD connector 15, an I/O (input/output) connector 16, a power coil/devices 18, connectors 19, etc.

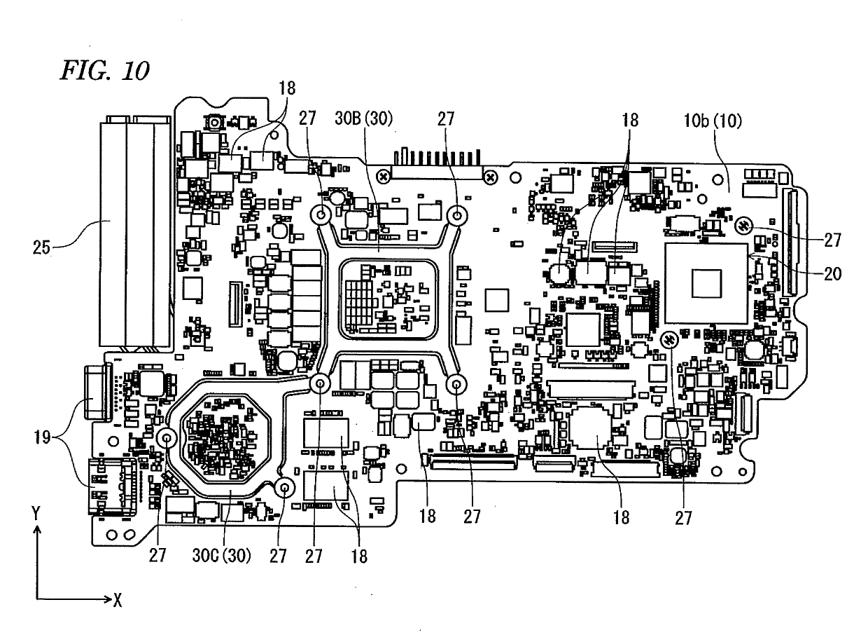

FIG. 10 is a plan view the circuit board 10 as viewed from the side of a surface 10b. The surface 10b of the circuit board 10 is mounted with a PCH (platform controller hub) 20, devices 18, connectors 19, etc. The PCH 20 is an example heat generation body. The circuit board 10 may be mounted with other heat generation bodies.

In the embodiment, the CPU 11, the graphic controller 12, the PCH 20, etc. are example ICs (integrated circuits) mounted on the circuit board 10, example heat generation bodies, and example components (modules, devices, electronic components, mounted components) having relatively large sizes. The CPU 11 is a component that generates heat most. The circuit board 10 which is mounted with the above components is disposed between the top wall 2c and the bottom wall 2d of the cabinet 2a. The power circuit component 13 is an example component (heat generation body, module, device) that generates a relatively large amount of heat.

In the embodiment, reinforcement plates (reinforcement members) 30 are provided in association with components such as the CPU 11, the graphic controller 12, and the PCH 20 that are mounted on the circuit board 10 and have relatively large sizes. The reinforcement plates 30 can reinforce the circuit board 10 and increase its rigidity. Therefore, for example, the reinforcement plates 30 can prevent components etc. from receiving high stress because of an external load.

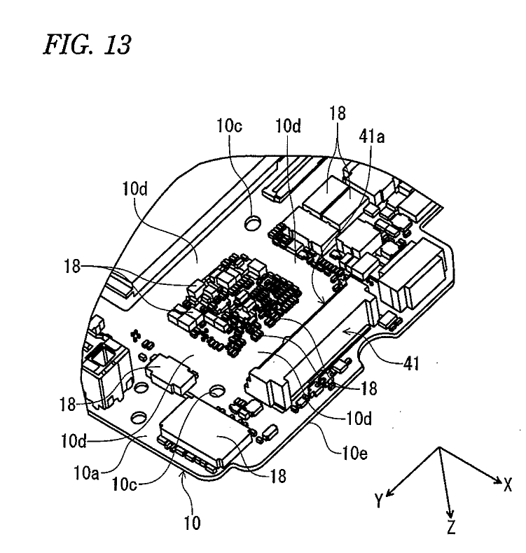

As shown in FIG. 9, a reinforcement plate 30A is mounted on the surface 10a of the circuit board 10 in association with the PCH 20, that is, on the back side of the PCH 20. As shown in FIG. 10, a reinforcement plate 30B is mounted on the surface 10b of the circuit board 10 in association with the CPU 11, that is, on the back side of the CPU 11. As shown in FIG. 10, a reinforcement plate 30C is mounted on the surface 10b of the circuit board 10 in association with the graphic controller 12, that is, on the back side of the graphic controller 12. Each reinforcement plate 30 is fixed to the circuit board 10 with fixing members 27 such as screws or studs with a screw. A male screw portion (not shown) of each fixing member 27 is inserted through a through-hole 10c (see FIG. 13) of the circuit board 10 from the opposite side of the circuit board 10 to the associated reinforcement plate 30 and fastened to a female screw hole of the reinforcement plate 30. In the case of a fixing member 27 being a stud with a screw, a projection portion (not shown) that is opposite to a male screw portion is formed with a female screw hole (not shown). A pressing portion 29 is fixed to a tip portion of the projection portion with a screw 28 that is fastened to the female screw hole. The pressing member (fixing member) 29 is used for pressing the heat sink 23, the heat pipe 24, or the like against the CPU 11, the graphic controller 12, or a like component.

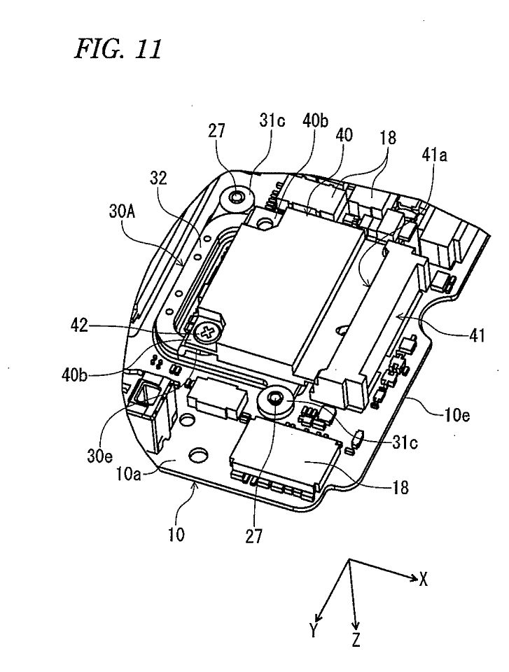

FIG. 11 is a perspective view of a portion, provided with the reinforcement plate 30A in association with the PCH 20, of the circuit board 10. As shown in FIG. 11, the reinforcement plate 30A is covered with a wireless LAN (local area network) module 40. The wireless LAN module 40 is connected to a connector 41. The wireless LAN module 40 is an example housed component (module, component).

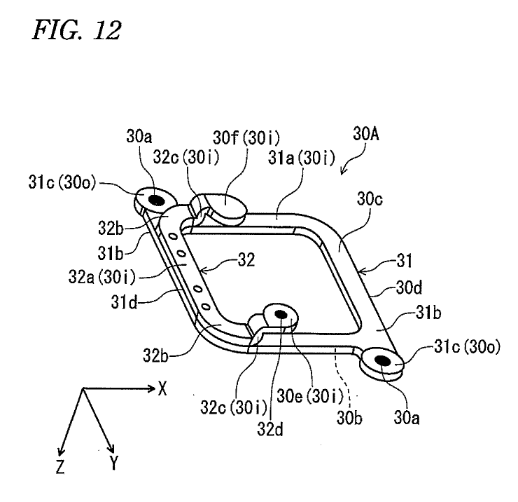

FIG. 12 is a perspective view of the reinforcement plate 30A. The reinforcement plate 30A is an integral member of a first member 31 and a second member 32. The first member 31 has an annular portion 31a, corner portions 31b, projections 31c, and an end portion 31d. The annular portion 31a is shaped like a rectangular ring. The corner portions 31b are located at diagonal positions of the annular portion 31a. The projections 31c project from the respective corner portions 31b away from the annular portion 31a and are shaped like a circular disc. The projections 31c are formed with respective screw holes 30a. The end portion 31d is one side portion of the annular portion 31a.

The second member 32 has a base portion 32a, end portions 32b, projections 32c, and receiving portions 30e and 30f. The base portion 32a is placed on and extends parallel with the end potion 31d of the first member 31. The base portion 32a is bent at both end portions 32b and thereby shaped like a character U. The projections 32c project (are erected) from both end portions 32b away from the first member 31. The receiving portions 30e and 30f are located at the tips of the respective projections 32c, are parallel with the first member 31, and are shaped like a circular disc. The receiving portion 30e is formed with a female screw 32d. In the embodiment, the second member 32 is an example support portion and the base portion 32a is an example first end portion.

The first member 31 and the second member 32 are integrated with (connected to) each other by welding (e.g., spot welding), for example. In the embodiment, for example, the end portion 31d of the first member 31 and the base portion 32a of the second member 32 are connected to each other at plural positions (e.g., four positions) by spot welding.

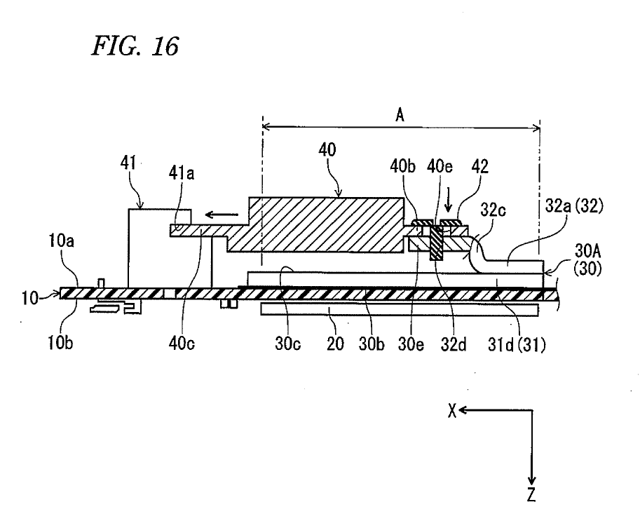

Each reinforcement plate 30 is disposed parallel with the surface 10a or 10b of the circuit board 10 preferably in contact with the surface 10a or 10b. In the embodiment, the reinforcement plate 30A is disposed on the side of the surface 10a and has a first surface 30b (see FIG. 16) that is in contact with the surface 10a and a second surface 30c that is opposite to the first surface 30b and is exposed to the inside space of the cabinet 2a. Where a reinforcement plate 30 is disposed on the side of the surface 10b of the circuit board 10, its first surface 30b is in contact with the surface 10b and its second surface 30c is exposed to the inside space of the cabinet 2a.

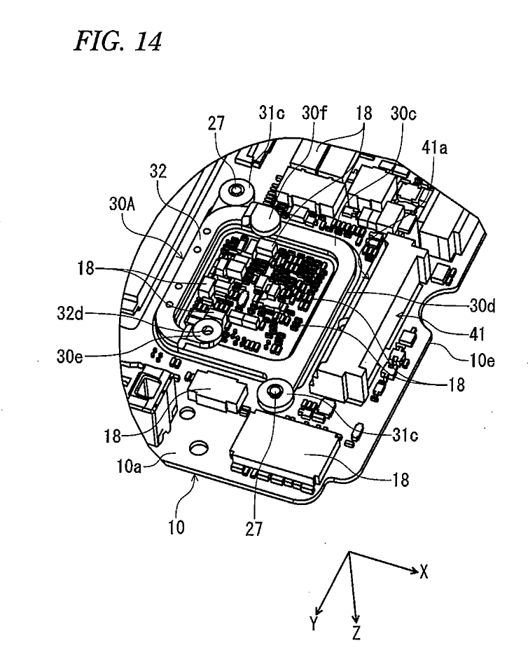

FIG. 13 is a perspective view of a region (non-mounting region) 10d, where the reinforcement plate 30A is to be disposed, of the circuit board 10. FIG. 13 shows the same portion as shown in FIG. 11 and shows a state that the wireless LAN module 40 and the reinforcement plate 30A are removed. FIG. 14 is a perspective view of the same portion as shown in FIG. 11 and shows a state that the wireless LAN module 40 is removed, that is, a state before attachment of the wireless LAN module 40. As shown in FIG. 13, through-holes 10c through which fixing members 27 are to be inserted are formed through the circuit board 10. The surface 10a of the circuit board 10 is provided with the component non-mounting region 10d which is a rectangular-ring-shaped region corresponding to the reinforcement plate 30A. Plural, relatively small (low-height) devices (components, modules) 18 are mounted inside the non-mounting region 10d. As shown in FIG. 14, the reinforcement plate 30A is set in the non-mounting region 10d and fixing members 27 are fastened to the respective projections 31c, whereby the reinforcement plate 30A is fixed to the circuit board 10. The devices 18 disposed inside the non-mounting region 10d are example third modules.

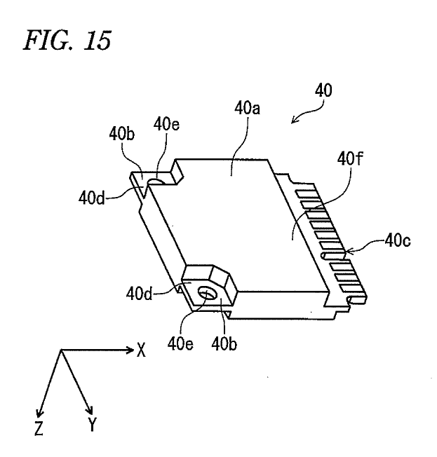

FIG. 15 is a perspective view of the wireless LAN module 40. As shown in FIG. 8 etc., the wireless LAN module 40 has a rectangular or square appearance when viewed in the thickness direction. The wireless LAN module 40 has a body 40a, flanges 40b, and connector pins 40c. The body 40a has a flat, rectangular parallelepiped shape. The flanges 40b are relatively thin, plate-like portions which are two corner portions 40d located at the two ends of one sideline of the rectangle. Through-holes 40e are formed through the respective flanges 40b. The connector pins 40c extend outward from an end portion (side portion) 40f that is opposite to the two corner portions 40d so as to have approximately a constant length, and are arranged alongside the end portion 40f.

As shown in FIGS. 11, 14, etc., a connector 41 has a long and narrow rectangular parallelepiped shape. The connector 41 is disposed between an edge 10e of the circuit board 10 and an edge 30d of the reinforcement plate 30A and extends alongside the edge 10e. The edge 10e of the circuit board 10, the connector 41, and the edge 30d of the reinforcement plate 30A are parallel with each other. The connector 41 is fixed to the surface 10a by soldering, for example.

FIG. 16 is a sectional view taken along line XVI-XVI in FIG. 9. The connector 41 is provided with a connection portion 41a which has an opening on the side of the reinforcement plate 30A at a position that is spaced from the surface 10a of the circuit board 10. The connection portion 41a is connected to the connector pins 40c of the wireless LAN module 40. A worker inserts the connector pins 40c of the wireless LAN module 40 into the connection portion 41a of the connector 41 and then puts the flanges 40b of the wireless LAN module 40 on the respective receiving portions 30e and 30f of the reinforcement plate 30A. Then, the worker fastens a fixing member 42 such as a screw that is inserted in the through-hole 40e of the one flange 40b to the female screw hole 32d of the receiving portion 30e of the reinforcement plate 30A. Whereas the connection portion 41a allows the wireless LAN module 40 to move in such a direction that the connector pins 40c are released from the connection portion 41a (rightward in FIG. 16) and to rotate in such a direction that the flanges 40b are elevated (upward in FIG. 16), the connection portion 41a prohibits the wireless LAN module 40 from moving or rotating in the other directions. Therefore, when the one flange 40b is fixed to the receiving portion 30e with the fixing member 42, the wireless LAN module 40 can be fixed so as to maintain the state of FIGS. 11 and 16. As such, the receiving portion 30e is an example stopping portion (fixing portion). On the other hand, the other flange 40b is placed on but is not fixed to the receiving portion 30f. As such, the receiving portion 30f is an example placement portion (support portion). The receiving portion 30e is an example second end portion and the receiving portion 30f is an example third end portion.

As seen from FIG. 16, the wireless LAN module 40 is disposed over and parallel with the surface 10a of the circuit board 10 at such a position as to be distant from the surface 10a. Both ends of the wireless LAN module 40 are supported by the reinforcement plate 30A and the connector 41.

As seen from FIG. 16, the wireless LAN module 40 is disposed in the region that is located on the back side of the PCH 20. Interconnections (not shown) of the circuit board 10 are formed in a region (in the surface 10b or 10a of the circuit board 10) on the bask side of a region where a relatively large component (module, first module) such as the CPU 11, the graphic controller 12, or the PCH 20 is mounted. Therefore, in such a region, it is difficult to dispose a support component (a support member, a fixing member, a support component, a fixing component, a connector, a stud, or the like having portions to be inserted into the circuit board 10) for supporting or fixing another component (module, second module). As a result, conventionally, in a region on the back side of such a relatively large component, a component (module, second module) that requires disposition of such a support component there is not disposed.

In the embodiment, attention is paid to the fact that a reinforcement plate 30 may be disposed in a region on the back side of such a relatively large component (module, first module), and such a reinforcement plate 30 is used for support and fixing of another component (module, second module). According to the embodiment, since another component (module, second module) can be disposed more easily in a region on the back side of a relatively large component (module, first module), components (modules) can be arranged more efficiently on the circuit board 10. This makes it possible to miniaturize the circuit board 10, hence the cabinet 2a (first unit 2), and consequently the personal computer 1. In the embodiment, the surface 10b of the circuit board 10 is an example first surface, the PCH 20 is an example first module, and the surface 10a of the circuit board 10 is an example second surface. The wireless LAN module 40 is an example second module, and the reinforcement plate 30A is an example reinforcement member.

As shown in FIG. 12, the reinforcement plate 30A has the annular portion 31a of the first member 31 and the base portion 32a, the projections 32c, and the receiving portions 30e and 30f of the second member 32 as inside portions 30i that are located on the back side of the PCH 20 and inside the periphery of a region A (see FIGS. 9 and 16), corresponding to the region of the PCH 20, in the surface 10a. The reinforcement plate 30A also has the projections 31c of the first member 31 as outside portions 30o that are located outside the region A in the surface 10a. As such, in the embodiment, the reinforcement plate 30A is a member having the outside portions 30o that are located outside the region A and fixed to the reinforcement plate 30A and the inside portions 30i that are located inside the periphery of the region A and connected to the outside portions 30o. The reinforcement plate 30A supports and fixes the wireless LAN module 40 by means of the inside portions 30i. Therefore, as shown in FIG. 16, the wireless LAN module 40 can be disposed on the back side of the PCH 20 inside the region corresponding to the region of the PCH 20 so as to be spaced from the surface 10a. This makes it easier to increase the efficiency of mounting of components on the circuit board 10.

As shown in FIG. 9, the connector 41 which serves as one supporting point of the wireless LAN module 40 is disposed outside the region A, that is, outside the periphery of the reinforcement plate 30A. The connector 41 can thus be disposed more easily on the circuit board 10. Furthermore, the connector pins 40c which are located at one end of the wireless LAN module 40 are supported by (electrically connected to) the connector 41 outside the periphery of the reinforcement plate 30A and the flanges 40b which is located at the other end are supported by or fixed to the reinforcement plate 30A inside the periphery of the reinforcement plate 30A. Therefore, the wireless LAN module 40 can be disposed inside the periphery of the reinforcement plate 30A more easily without being electrically connected to the circuit board 10. In the embodiment, the flanges 40b are example first support portions and the connector pins 40c are example second support portions.

As shown in FIG. 9, on the circuit board 10, the connector 41 is disposed on the opposite side of the reinforcement plate 30A (PCH 20) to such components (modules, third modules) as the memory slot connectors 14 and the CPU 11. A relatively large number of interconnections are formed in the region of the circuit board 10 between the PCH 20 and the memory slot connectors 14, the CPU 11, etc., that is, in the region of the circuit board 10 inside the PCH 20, and hence there may occur a case that it is difficult to dispose the connector 41. In this respect, in the embodiment, since the connector 41 is disposed on the opposite side of the reinforcement plate 30A (PCH 20) to such components (modules, fourth modules) as the memory slot connectors 14 and the CPU 11, that is, at a peripheral position of the circuit board 10, interference between interconnections can be suppressed easily and the connector 41 can be disposed more easily. Furthermore, in the embodiment, since the connector 41 is disposed at the edge 10e of the circuit board 10 (or in its vicinity; at a peripheral position of the circuit board 10) where a relatively small number of interconnections are formed, interference between interconnections can be suppressed easily and the connector 41 can be disposed more easily.

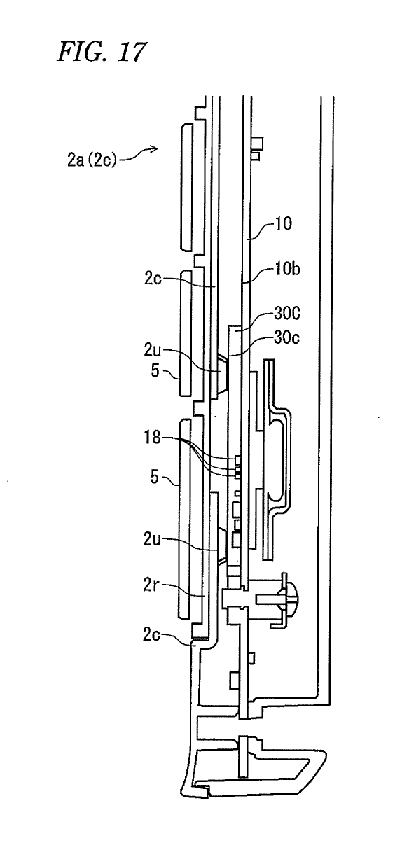

FIG. 17 is a sectional view of part of the first unit 2 of the personal computer 1 according to the embodiment. As shown in FIG. 17, in the embodiment, projections 2u (see FIG. 7) which are formed on the back surface 2t of the top wall 2c of the cabinet 2a are in contact with a second surface 30c of the reinforcement plate 30C which is disposed on the surface 10b of the circuit board 10. That is, the reinforcement plate 30C functions as a support portion (contact portion) for the projections 2u (top wall 2c). Therefore, the reinforcement plate 30C can suppress a phenomenon that the top wall 2c is depressed or bent toward the inside of the cabinet 2a. That portion of the top wall 2c which is formed with the projections 2u corresponds to part of the bottom wall of the recess 2r where the keyboard 5 is housed (placed). Therefore, a phenomenon that the keyboard 5 as a component (module) provided in (or supported by) the top wall 2c sinks, rises, springs up, moves upward or downward, vibrates, or does alike action. Although only the reinforcement plate 30C is shown in FIG. 17, associated projections 2u (see FIG. 7) are in contact with the reinforcement plate 30B.

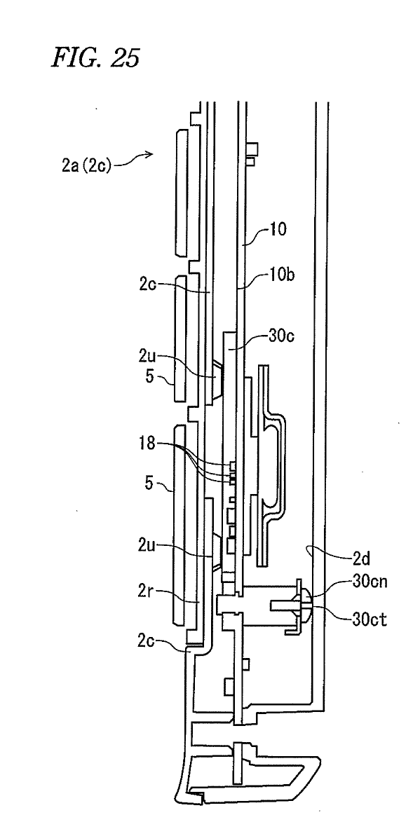

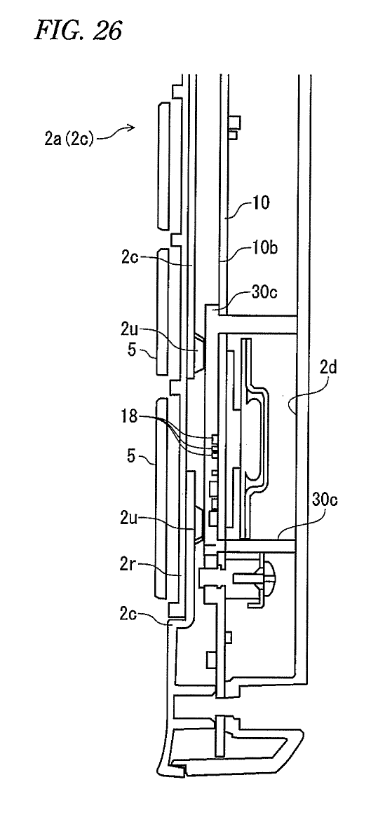

Modifications will be described below with reference to FIGS. 25 and 26.

As shown in FIG. 25, to increase the strength of the support by the reinforcement plate 30C, it is preferable to employ a structure capable of supporting both of the top wall 2c and the bottom wall 2d. In the modification of FIG. 25, the ribs (projections 2u) are formed on the top wall 2c at such positions as to be opposed to the reinforcement plate 30C and the screw heads 30ct of screws 30cn for fixing the reinforcement plate 30C are made in contact with the bottom wall 2d. Whereas the projections 2u are not in contact with the reinforcement plate 30C in an ordinary state, they come into contact with the reinforcement plate 30C when pressure is exerted to the cabinet 2a and top wall 2c and the bottom wall 2d are thereby displaced inward. The cabinet 2a is thus prevented from being deformed excessively. The force acting on the reinforcement plate 30C can be received by the bottom wall 2d via the screws 30cn for fixing the reinforcement plate 30C.

FIG. 26 shows another modification of the same kind. The reinforcement plate 30C itself that penetrates through the circuit 10 is in contact with the bottom wall 2d so that external stress is diverted to the wall of the cabinet 2a that is opposite to the wall depressed. The structure of FIG. 26 provides the same advantage as that of FIG. 25.

These structures can also be applied to the TV receiver 100 according to the first embodiment. In particular, the strength of electronic apparatus which are prone to be deformed by external stress and electronic apparatus having a touch screen (provided with no keyboard) can be increased by using the above structures.

In the above-described second embodiment, the reinforcement plate 30A is used for supporting and fixing the wireless LAN module 40 which is an example housed component (module, component). Therefore, the number of components can be made smaller than in a case that the circuit board 10 is provided with separate components for supporting and fixing the wireless LAN module 40, which in turn makes it easier to arrange interconnections on the circuit board 10.

In the embodiment, the reinforcement plate 30A has the second member 32 as a support portion. Therefore, the reinforcement plate 30A can be increased in rigidity and can be manufactured more easily. The reinforcement plate 30A having the function of supporting and fixing a housed component can be manufactured more efficiently by effectively utilizing a conventional reinforcement plate having no support portions. Furthermore, both of the functions (the reinforcement of the circuit board 10 and the support and fixing of a housed component) of the reinforcement plate 30A can be satisfied more easily by, for example, making the specifications (material quality, flexural rigidity, etc.) of the first member 31 different from those of the second member 32. The first member 31 and the second member 32 may be connected to each other by a method other than welding, such as screwing, bonding, or engaging. The first member 31 and the second member 32 may be made of a metal material, a synthetic resin material, or the like.

In the embodiment, the wireless LAN module 40 as an example housed component is supported by the connector 41 (example support component) outside the annular portion 31a of the reinforcement plate 30A. In this manner, housed components having larger sizes can be disposed more easily. And it becomes easier to electrically connect housed components to the circuit board 10.

In the embodiment, the flanges 40b (first support portions) of the wireless LAN module 40 are put on the reinforcement plate 30A from the side that is opposite to the circuit board 10. Therefore, the wireless LAN module 40 as an example housed component can be supported by and fixed to a reinforcement plate more easily.

In the embodiment, the wireless LAN module 40 as an example housed component is supported by or fixed to the connector 41 (support member). Therefore, the number of components can be made smaller than in a case that the circuit board 10 is provided with separate components for supporting and fixing the wireless LAN module 40.

In the embodiment, the wireless LAN module 40 as an example housed component is supported by or fixed to the two (in general, plural) receiving portions 30e and 30f (first end portion and third end portion) of the reinforcement plate 30A. This makes it possible to support the wireless LAN module 40 more stably. The wireless LAN module 40 as an example housed component is fixed to the receiving portion 30e and supported by the receiving portion 30f. This makes the time and labor taken to attach the wireless LAN module 40 less than in a case that the wireless LAN module 40 is fixed to a reinforcement plate at plural positions.

In the embodiment, the personal computer 1 is equipped with the PCH 20, the wireless LAN module 40, and the reinforcement plate 30A. The PCH 20 is an example module that is disposed on the surface 10b (first surface) of the circuit board 10. The wireless LAN module 40 is an example module that is disposed on the surface 10a (second surface) of the circuit board 10. The reinforcement plate 30A is an example reinforcement member that is disposed on the surface 10a, that is, disposed on the side (back side) opposite to the PCH 20, reinforces the circuit board 10, and supports the wireless LAN module 40. That is, the wireless LAN module 40 is located in the region of the surface 10a that corresponds to the region of the opposite surface 10b where the PCH 20 is mounted. Therefore, in the embodiment, the efficiency of mounting of components on the circuit board 10 can be increased and hence the degree of freedom of layout of components on the circuit board 10 can be increased.

The reinforcement plate 30A is an example member that has the inside portions 30i that are located on the side opposite to the PCH 20 and in a peripheral portion of or inside the periphery of the region A of the surface 10a and the outside portions 30o that are located outside the region A and that supports and fixes the wireless LAN module 40 by means of the inside portions 30i. That is, in the embodiment, the reinforcement plate 30A as such a member can be used for support and fixing of the wireless LAN module 40. Therefore, the number of components can be made smaller than in a case that the circuit board 10 is provided with separate components for supporting and fixing the wireless LAN module 40.

Furthermore, since the wireless LAN module 40 can be located in the region of the surface 10a that corresponds to the region of the opposite surface 10b where the PCH 20 is mounted. Therefore, in the embodiment, the efficiency of mounting of components on the circuit board 10 can be increased and hence the degree of freedom of layout of components on the circuit board 10 can be increased.

Plural modifications will be described below, in each of which part of the components etc. of the first embodiment or the second embodiment are replace by other ones. In each of the following embodiments, only the replacement components etc. will be described mainly. The structures etc. of non-described or non-illustrated components etc. are basically the same as in the first or second embodiment. Therefore, in each of the following modifications, the effects and advantages exhibited or obtained by those non-described or non-illustrated components etc. are obtained likewise.

### First Modification

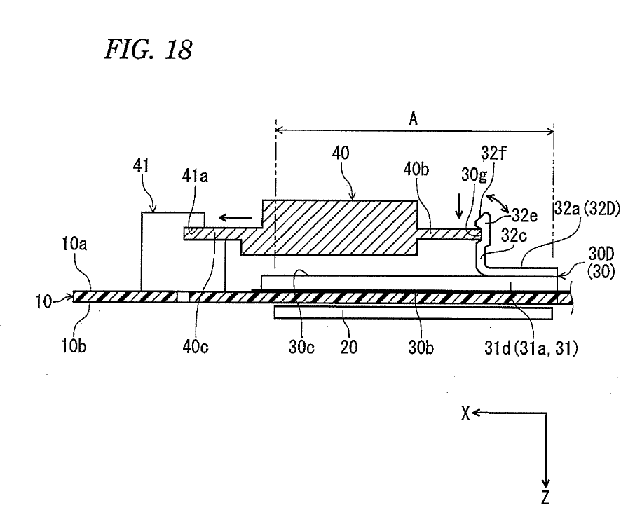

FIG. 18 is a sectional view of part of an example circuit board 10 having a reinforcement plate 30D according to a first modification. In this modification, the reinforcement plate 30D capable of replacing the reinforcement plate 30A has a second member 32D in place of the second member 32. Projections 32c of the second member 32D is capable of elastic deformation and is deformed elastically when the wireless LAN module 40 is attached. More specifically, the connector pins 40c of the wireless LAN module 40 are inserted into the connection portion 41a of the connector 41 (shown on the left side in FIG. 18) with fingers of a worker and then the flanges 40b of the wireless LAN module 40 are brought close to tip portions 32e of the second member 32D from above (see FIG. 18). The tip portions 32e are formed with respective slant surfaces 32f. Therefore, the flanges 40b that have come into contact with the respective slant surfaces 32f as a result of downward pressing deforms the second member 32D elastically in such a direction that its tip portions 32e go away from the connector 41. As a result, the interval between the connector 41 as one support portion and the second member 32D as another support portion is increased to establish a state that the wireless LAN module 40 can reach its holding position. The flanges 40b climb over the tip portions 32e and reach holding portions 30g, respectively, which are, for example, recesses of the second member 32D. At this time, the tip portions 32e of the second member 32D return toward the connector 41. As described above, according to this modification, the state that the wireless LAN module 40 as an example housed component is supported by the reinforcement plate 30D can be obtained more easily by a simpler attachment manipulation (e.g., one-touch manipulation).

### Second Modification

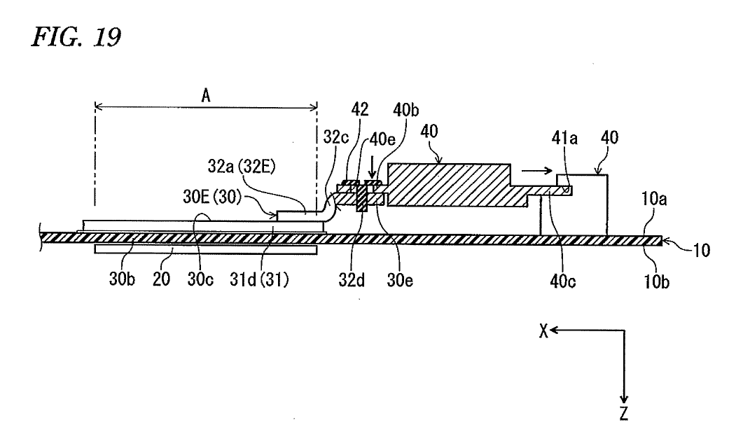

FIG. 19 is a sectional view of part of an example circuit board 10 having a reinforcement plate 30E according to a second modification. In this modification, the reinforcement plate 30E capable of replacing the reinforcement plate 30A has a second member 32E in place of the second member 32. Part of the second member 32E projects outward from the periphery of the region A of the surface 10a that corresponds to the region of the PCH 20 in the opposite surface 10b, and the wireless LAN module 40 as an example housed component is located outside the periphery of the region A. The reinforcement plate 30E according to this modification can also be used for support and fixing of the wireless LAN module 40 as an example housed component.

### Third Modification

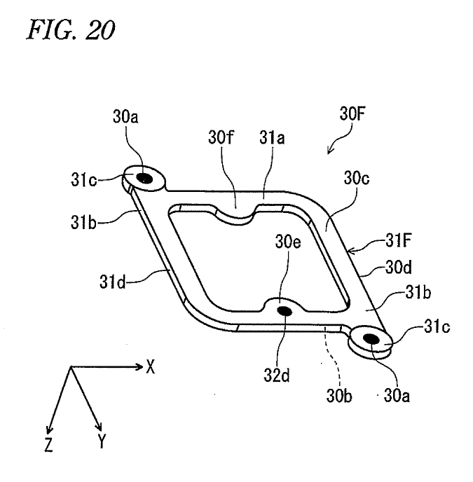

FIG. 20 is a perspective view of an example reinforcement plate 30F according to a third modification. In the reinforcement plate 30F according to this medication which can replace the reinforcement plate 30A, a first member 31F has receiving portions 30e and 30f. The reinforcement plate 30F according to this modification can also be used for support and fixing of the wireless LAN module 40 as an example housed component. This modification is more effective in the case where the wireless LAN module 40 can be set closer to the surface 10a of the circuit board 10. The distance from the surface 10a of the circuit board 10 can be increased by increasing the thickness of the first member 31F entirely or partially. In this modification, the receiving portions 30e and 30f are example contact portions.

### Fourth Modification

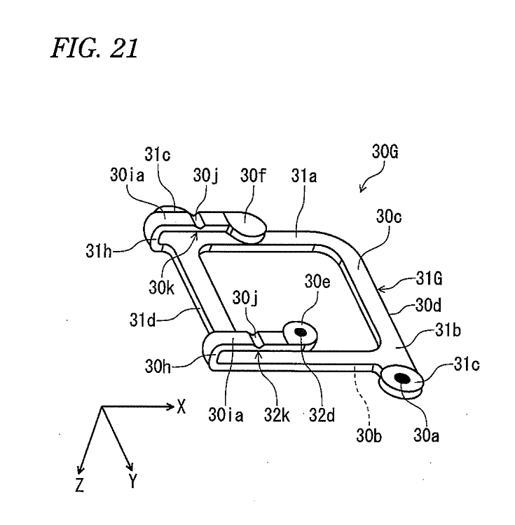

FIG. 21 is a perspective view of an example reinforcement plate 30G according to a fourth modification. In the reinforcement plate 30G according to this medication which can replace the reinforcement plate 30A, receiving portions 30e and 30f are provided at positions that are spaced from the surface 10a of the circuit board 10 by bending a first member 31G. More specifically, projections 30h project (is erected) from peripheral positions of an annular portion 31a away from the surface 10a of the circuit board 10, arms 30ia project from the tips of the respective projections 30h to the side of the annular portion 31a parallel with the surface 10a, and the receiving portions 30e and 30f are provided at the tips of the arms 30ia. The receiving portions 30e and 30f may be located either at the same positions as or at different positions than in the reinforcement plate 30A. According to this modification, the number of members constituting a reinforcement plate can be reduced and the time and labor taken to manufacture a reinforcement plate can be reduced. Also in this modification, the receiving portions 30e and 30f are example contact portions.

Furthermore, in this modification, the arms 30ia are formed with recesses 30j to form narrow portions 30k, respectively. The elasticity (rigidity or bendability) of the arms 30ia can be set in a desired manner utilizing the narrow portions 30k. The narrow portions 30k may be formed as easy-to-break portions which are broken more easily than the other portions when external force such as an impact load is exerted on the arms 30ia.

### Fifth Modification

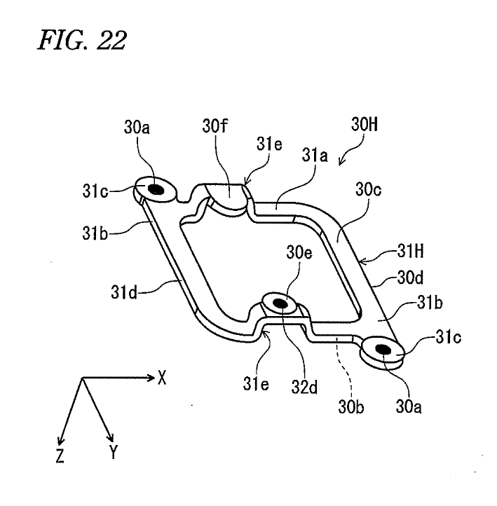

FIG. 22 is a perspective view of an example reinforcement plate 30H according to a fifth modification. In the reinforcement plate 30H according to this medication which can replace the reinforcement plate 30A, receiving portions 30e and 30f are provided at positions that are spaced from the surface 10a of the circuit board 10 by bending a first member 31H. More specifically, two sides, opposed to each other, of an annular portion 30a are formed with respective projections 31e having an inverted-U shape and the receiving portions 30e and 30f are formed at the tips of the respective projections 31e. The receiving portions 30e and 30f may be located either at the same positions as or at different positions than in the reinforcement plate 30A. According to this modification, the number of members constituting a reinforcement plate can be reduced and the time and labor taken to manufacture a reinforcement plate can be reduced.

### Sixth Modification

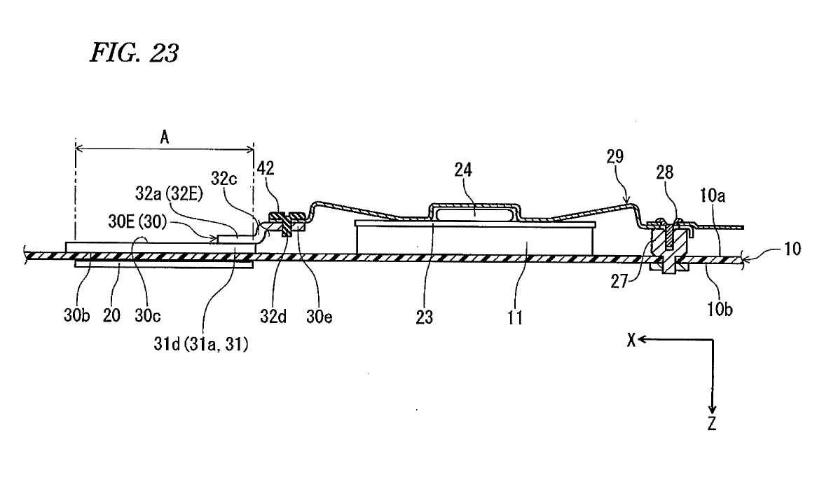

FIG. 23 is a sectional view of part of an example circuit board 10 having a reinforcement plate 30E according to a sixth modification. In this modification, the reinforcement plate 30E which is configured in the same manner as in the second modification supports and fixes a pressing member 29 as an example housed component. According to this modification, the number of members for supporting the pressing member 29 and fixing it to the circuit board 10 can be reduced. That is, the number of components can be made smaller than in a case that the circuit board 10 is provided with separate components for supporting and fixing the pressing member 29, which in turn makes it easier to arrange interconnections on the circuit board 10. Furthermore, in this modification, since receiving portions 30e and 30f are located between the PCH and the CPU 11 which are modules (components), interconnections and the pressing member 29 can both be arranged or disposed in a desired manner in the region, between these modules, of the circuit board 10.

### Seventh Modification

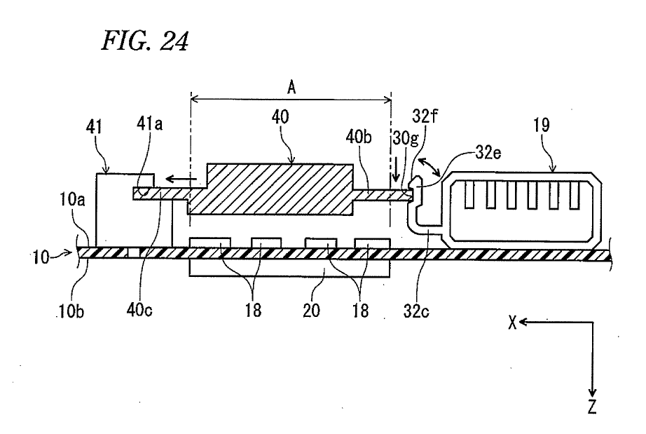

FIG. 24 is a sectional view of part of an example circuit board 10 having a connector 19 as a support member according to a seventh modification. In this modification, the connector 19 which is an example module (component, fifth module) provided on the circuit board 10 is an example support member for the wireless LAN module 40 as an example housed component. As in the first modification, the connector 19 has projections 32c capable of elastic deformation. Therefore, as in the first modification, a state that the wireless LAN module 40 as an example housed component is supported by the connector 19 can be obtained more easily by a simpler attachment manipulation (e.g., one-touch manipulation). Furthermore, the number of components can be reduced, which in turn makes it easier to arrange interconnections on the circuit board 10. Other example support members are connectors other than the connector 19 and modules (components) not having a connector. The support portion(s) to directly support a housed component may be a body (housing, casing, or the like) of a module or, as shown in FIG. 24, projections that project from a body or the like. The method by which support portion(s) supports a housed component is not limited to elastic engagement and may be any of various methods such as screwing.

Although the preferred embodiments of the invention have been described above, the invention is not limited to those embodiments and their modifications and further various modifications are possible. The invention can also be applied to components (housed components, modules) other than a wireless LAN module.

The invention may be practiced in such a manner that the specifications (structure, shape, size, length, width, thickness, height, number, arrangement, position, material quality, etc.) of the electronic apparatus (TV receiver, personal computer), circuit board, electronic components, reinforcement plates, reinforcement members, housed components, modules, first modules, second modules, components, support portions, connectors, members, connection portions, first end portions, second end portions, third end portions, first surface, second surface, etc. are changed as appropriate.

The exemplary embodiments make it possible to increase the mounting efficiency of components (modules, devices) on a circuit board.

What is claimed is:

1. A TV receiver comprising:
a cabinet having a wall that is provided with a manipulation surface;
a circuit board housed in the cabinet;
an electronic component provided on the circuit board;
a reinforcement plate having a first surface that is in contact with the circuit board and a second surface that is opposite to the first surface and is exposed to an internal space of the cabinet; and
a projection that is located in a region of the wall on a backside of the manipulation surface, and is projected from the region toward the reinforcement plate, and configured to come into contact with the reinforcement plate to suppress deformation of the wall when the wall is bent toward the internal space of the cabinet.

2. The TV receiver according to claim 1, wherein the projection is shaped to extend alongside a periphery of the reinforcement plate.

3. The TV receiver according to claim 2, wherein:
the electronic component has four sides;
the reinforcement plate has portions that extend alongside the four respective sides and are opposed to the four respective sides with the circuit board interposed in between; and
the projection is shaped to project toward the portions of the reinforcement plate that extend alongside the four respective sides of the electronic component.

4. The TV receiver according to claim 2, wherein the projection comprises plural projections which are shaped to extend toward respective sides of the reinforcement plate.

5. An electronic apparatus comprising:
a cabinet having a surface that is provided with a keyboard;
a circuit board housed in the cabinet;
an electronic component provided on the circuit board;
a reinforcement plate having a first surface that is in contact with the circuit board and a second surface that is opposite to the first surface and is exposed to an internal space of the cabinet; and
a projection which projects from a back side of the surface of the cabinet toward the reinforcement plate.

6. The electronic apparatus according to claim 5, wherein the projection is shaped to extend alongside a periphery of the reinforcement plate.

7. The electronic apparatus according to claim 6, wherein:
the electronic component has four sides;
the reinforcement plate has portions that extend alongside the four respective sides and are opposed to the four respective sides with the circuit board interposed in between; and
the projection is shaped to project toward the portions of the reinforcement plate that extend alongside the four respective sides of the electronic component.

8. The electronic apparatus according to claim 6, wherein:
the keyboard comprises an enter button; and
the projection is located around a position that is under the enter button.

9. An electronic apparatus comprising:
a cabinet;
a circuit board housed in the cabinet;
an electronic component provided on the circuit board;
a reinforcement plate having a first surface at least part of which is in contact with the circuit board and a second surface that is opposite to the first surface; and
a projection that projects from an inner surface of the cabinet toward the reinforcement plate.

10. The electronic apparatus according to claim 9, wherein the projection is shaped to extend alongside a periphery of the reinforcement plate.
